(19) United States
(12) Patent Application Publication
(10) Pub. No.: US 2007/0094870 A1
(43) Pub. Date: May 3, 2007

(54) Wiring board, method of manufacturing the same, semiconductor device, and electronic instrument

(75) Inventors: Tetsuya Otsuki, Fujimi (JP); Hirofumi Kurosawa, Tatsuno (JP); Hiroshi Miki, Fujimi (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 11/639,845

(22) Filed: Dec. 15, 2006

Related U.S. Application Data
(62) Division of application No. 10/791,651, filed on Mar. 2, 2004.

(30) Foreign Application Priority Data
Mar. 3, 2003 (JP) 2003-55643
Mar. 3, 2003 (JP) 2003-55644

(51) Int. Cl. H05K 3/36

(52) U.S. Cl. 29/830; 29/831; 29/846

(57) ABSTRACT

A receiving layer formed of a thermoplastic resin is softened by applying heat. By using a solvent containing conductive particles, an interconnect layer is formed on the receiving layer which is softened by the application of heat. The conductive particles are bonded together by heating the interconnect layer.

### CROSS-REFERENCE TO RELATED APPLICATIONS

This application is a divisional of U.S. patent application Ser. No. 10/791,651 filed on Mar. 2, 2004. This application claims the benefit of Japanese Patent Application No. 2003-55643, filed on Mar. 3, 2003, and Japanese Patent Application No. 2003-55644, filed on Mar. 3, 2003. The disclosures of the above applications are incorporated herein by reference.

### BACKGROUND OF THE INVENTION

The present invention relates to a wiring board, a method of manufacturing the same, a semiconductor device, and an electronic instrument.

Conventionally, a printed circuit board is manufactured by attaching copper foil to a base material and forming interconnects by etching. This complicates the process and makes it necessary to use an expensive mask for etching. Moreover, a number of pieces of equipment is necessary. A polyimide is generally used as the base material. However, since adhesion between the polyimides is low, it is difficult to manufacture a multilayer substrate.

In recent years, a technology of forming interconnects by ejecting metallic ink onto a surface-treated base material has been developed. In the case of controlling the surface tension of the metallic ink by forming a fluorine film on the base material (fluoroalkylsilane (FAS) treatment) and making the fluorine film porous as the surface treatment, it is difficult to increase adhesion between the interconnect and the base material. Moreover, interlayer separation easily occurs after stacking the base materials, whereby it is difficult to manufacture a highly reliable multilayer substrate. Furthermore, since the fluorine films cannot be stacked, a stacked structure may not be obtained.

As the surface treatment, a method of forming a receiving layer having swelling properties by applying a polyvinyl alcohol to the base material, or a method of forming a (porous) receiving layer having voids by applying aluminum hydroxide to the base material may be employed. However, since the receiving layer tends to contain moisture due to high hygroscopicity, the receiving layer is not suitable as an inner layer or an inner layer of the multilayer substrate. Moreover, it is difficult to increase adhesion between the interconnect and the base material. Since it is difficult to increase adhesion between the interconnect and the base material, interlayer separation easily occurs after stacking the base materials. Therefore, it is difficult to manufacture a highly reliable multilayer substrate.

### BRIEF SUMMARY OF THE INVENTION

A method of manufacturing a wiring board according to one aspect of the present invention includes:

softening a receiving layer formed of a thermoplastic resin by applying heat;

forming an interconnect layer on the receiving layer which is softened by the application of heat using a solvent containing conductive particles; and

causing the conductive particles to be bonded together by heating the interconnect layer.

A method of manufacturing a wiring board according to another aspect of the present invention includes:

forming a first interconnect layer on a first receiving layer formed of a thermoplastic resin which has been in a softened state by using a solvent containing conductive particles;

forming a second receiving layer in a softened state on the first receiving layer and the first interconnect layer by using a thermoplastic resin;

forming a second interconnect layer on the second receiving layer which has been in the softened state by using a solvent containing conductive particles; and

causing the thermoplastic resins of the first and second receiving layers to be softened and the conductive particles to be bonded together in a connecting portion of the first and second interconnect layers by applying heat.

A wiring board according to a further aspect of the present invention is manufactured by one of the above methods.

A semiconductor device according to a still further aspect of the present invention includes:

the above wiring board; and

a semiconductor chip electrically connected with the wiring board.

An electronic instrument according to a yet further aspect of the present invention includes the above semiconductor device.

### BRIEF DESCRIPTION OF THE SEVERAL VIEWS OF THE DRAWING

FIGS. 1A to 1D are illustrative of a method of manufacturing a wiring board according to a first embodiment of the present invention.

FIGS. 2A to 2C are illustrative of a method of manufacturing a wiring board according to the first embodiment of the present invention.

FIGS. 3A and 3B are illustrative of a method of manufacturing a wiring board according to the first embodiment of the present invention.

FIGS. 4A to 4D are illustrative of a method of manufacturing a wiring board according to a second embodiment of the present invention.

FIGS. 5A to 5C are illustrative of a wiring board according to a third embodiment of the present invention.

FIGS. 6A to 6D are illustrative of a method of manufacturing a wiring board according to a fourth embodiment of the present invention.

FIGS. 7A to 7C are illustrative of a method of manufacturing a wiring board according to the fourth embodiment of the present invention.

FIGS. 8A to 8C are illustrative of a method of manufacturing a wiring board according to the fourth embodiment of the present invention.

FIGS. 9A and 9B are illustrative of a method of manufacturing a wiring board according to the fourth embodiment of the present invention.

FIGS. 10A to 10C are illustrative of a method of manufacturing a wiring board according to a fifth embodiment of the present invention.

FIGS. 11A to 10C are illustrative of a method of manufacturing a wiring board according to the fifth embodiment of the present invention.

FIGS. 12A and 12B are illustrative of a method of manufacturing a wiring board according to a sixth embodiment of the present invention.

FIG. 13 shows a semiconductor device according to an embodiment to which the present invention is applied.

FIG. 14 shows an electronic instrument including a semiconductor device according to an embodiment to which the present invention is applied.

FIG. 15 shows another electronic instrument including a semiconductor device according to an embodiment to which the present invention is applied.

### DETAILED DESCRIPTION OF THE EMBODIMENT

Embodiments of the present invention may easily manufacture a highly reliable wiring board.

(1) A method of manufacturing a wiring board according to one embodiment of the present invention includes:

softening a receiving layer formed of a thermoplastic resin by applying heat;

forming an interconnect layer on the receiving layer which is softened by the application of heat using a solvent containing conductive particles; and

causing the conductive particles to be bonded together by heating the interconnect layer.

According to this method of manufacturing a wiring board, since the receiving layer is in a softened state when providing the solvent containing the conductive particles, occurrence of blurring or bulging can be prevented. Moreover, the hardened receiving layer has high adhesion to the interconnect layer including the bonded conductive particles. Therefore, a highly reliable wiring board can be easily manufactured.

(2) With this method of manufacturing a wiring board, the interconnect layer may be formed by ejecting the solvent containing the conductive particles.

(3) With this method of manufacturing a wiring board, the receiving layer may be formed on a base material.

(4) This method of manufacturing a wiring board may further include:

removing the base material from the receiving layer after causing the conductive particles to be bonded together.

(5) A wiring board according to another embodiment of the present invention is manufactured by the above method.

(6) A semiconductor device according to a further embodiment of the present invention includes:

the above wiring board; and

a semiconductor chip electrically connected with the wiring board.

(7) An electronic instrument according to a still further embodiment of the present invention includes the above semiconductor device.

(8) A method of manufacturing a wiring board according to a still further embodiment of the present invention includes:

forming a first interconnect layer on a first receiving layer formed of a thermoplastic resin which has been in a softened state by using a solvent containing conductive particles;

forming a second receiving layer in a softened state on the first receiving layer and the first interconnect layer by using a thermoplastic resin;

forming a second interconnect layer on the second receiving layer which has been in the softened state by using a solvent containing conductive particles; and

causing the thermoplastic resins of the first and second receiving layers to be softened and the conductive particles to be bonded together in a connecting portion of the first and second interconnect layers by applying heat.

According to this method of manufacturing a wiring board, since the first and second receiving layers are in a softened state when providing the solvent containing the conductive particles, occurrence of blurring or bulging can be prevented. Moreover, since the first and second receiving layers adhere to each other when the first and second receiving layers are in a softened state, interlayer separation does not occur or rarely occurs. Furthermore, the hardened first or second receiving layer has high adhesion to the first or second interconnect layer including the bonded conductive particles. Therefore, a highly reliable wiring board can be easily manufactured.

(9) With this method, the conductive particles included in the first interconnect layer may be dispersed in the solvent in a state in which each of the conductive particles is covered with a coating material for preventing a reaction between the conductive particles, and the method may further include decomposing the coating material by heating the first interconnect layer before forming the second receiving layer.

(10) With this method of manufacturing a wiring board, the first and second interconnect layers may be formed by ejecting the solvent containing the conductive particles.

(11) With this method of manufacturing a wiring board, the first receiving layer may be formed on a base material.

(12) This method of manufacturing a wiring board may further include:

removing the base material from the first receiving layer after causing the conductive particles to be bonded together in the connecting portion of the first and second interconnect layers.

(13) A wiring board according to a still further embodiment of the present invention is manufactured by any one of the above methods (8) to (12).

(14) A semiconductor device according to a still further embodiment of the present invention includes:

the above wiring board mentioned in (13); and

a semiconductor chip electrically connected with the wiring board.

(15) An electronic instrument according to a yet further embodiment of the present invention includes the above semiconductor device mentioned in (14).

The embodiments of the present invention are described below with reference to the drawings.

### First Embodiment

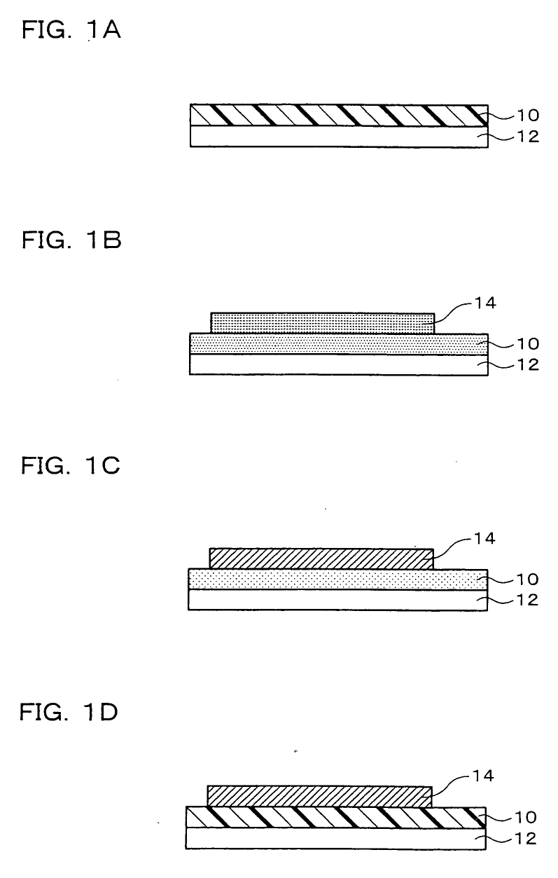

FIGS. 1A to 3B are illustrative of a method of manufacturing a wiring board according to a first embodiment of the present invention. In the present embodiment, a receiving layer 10 formed by using a thermoplastic resin (organic material such as a polyamide or a thermoplastic polyimide, for example) is used, as shown in FIG. 1A. The receiving layer 10 may be formed on a base material 12 (substrate, for example). The base material 12 may be formed of a metal such as copper, a thermosetting resin (polyimide or epoxy resin, for example), or glass. The receiving layer 10 may be formed to have a flat surface. The receiving layer 10 has insulating properties and may be called a (first) insulating layer.

As shown in FIG. 1B, the receiving layer 10 is softened by applying heat. The receiving layer 10 may have viscosity in this state. An interconnect layer 14 (hereinafter may be called “first interconnect layer”) is formed on the receiving layer 10 in a softened state. The interconnect layer 14 is formed by using a solvent containing conductive particles (metallic ink, for example). The conductive particles may be formed of a material which is rarely oxidized and has a low electrical resistance, such as gold or silver. As a solvent containing fine gold particles, “Perfect Gold” (manufactured by Vacuum Metallurgical Co., Ltd.) may be used. As a solvent containing fine silver particles, “Perfect Silver” (manufactured by Vacuum Metallurgical Co., Ltd.) may be used. There are no specific limitations to the size of the particles. The particles used herein are particles which can be ejected together with a solvent. The interconnect layer 14 may be formed by ejecting a solvent containing conductive particles using an ink-jet method or a Bubble Jet (registered trademark) method, or may be formed by mask printing or screen printing. The conductive particles may be covered with a coating material in order to prevent a reaction between the particles. The solvent may be dried to only a small extent and have resolubility. The conductive particles may be uniformly dispersed in a solvent.

According to the present embodiment, since the solvent containing conductive particles is provided on the thermoplastic resin in a softened state, occurrence of blurring or bulging can be prevented when forming the interconnect layer 14. The conductive particles (or conductive particles and coating material) may be allowed to remain by drying the interconnect layer 14 to volatilize the solvent. The interconnect layer 14 may be dried at a temperature from room temperature or more to 100° C. or less. The coating material which covers the conductive particles may be decomposed by heating the interconnect layer 14.

As shown in FIG. 1C, heat is applied to the interconnect layer 14. The interconnect layer 14 may be heated at a temperature at which the conductive particles in the interconnect layer 14 are bonded together (sintered, for example) (about 300-600° C., for example). The heat may be applied for about one hour. This causes the conductive particles to form a conductive film or a conductive layer. The thermoplastic resin may be further softened.

As shown in FIG. 1D, the receiving layer 10 is cooled to harden. The temperature of the receiving layer 10 may be decreased at ordinary temperature (or room temperature) instead of positively cooling the receiving layer 10. After the thermoplastic resin which makes up the receiving layer 10 is hardened and the conductive particles are bonded together, adhesion between the receiving layer 10 and the interconnect layer 14 is increased, whereby a highly reliable wiring board can be obtained.

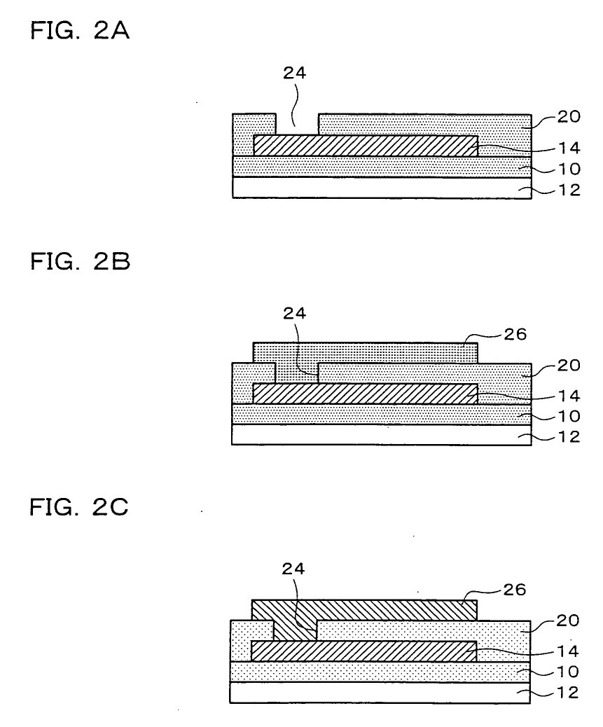

As shown in FIG. 2A, an insulating layer 20 (hereinafter may be called “second insulating layer”) may be formed on the receiving layer 10 so as to cover the interconnect layer 14. The description of the receiving layer 10 may be applied to the material for the insulating layer 20. In the case of forming the insulating layer 20, the solvent is volatilized from at least the interconnect layer 14 before forming the insulating layer 20. In the present embodiment, the isulating layer 20 is formed after causing the conductive particles in the interconnect layer 14 to be bonded together (sintered, for example). In the case of forming the insulating layer 20 by using a thermoplastic resin, the thermoplastic resin is softened by applying heat. In this case, the receiving layer 10 may be softened by the applied heat. A contact hole 24 is formed in the insulating layer 20.

As shown in FIG. 2B, a second interconnect layer 26 is formed on the insulating layer 20. The description of the first interconnect layer 14 may be applied to the material and the formation method for the second interconnect layer 26. Since the insulating layer 20 has the same function as the receiving layer 10 for the second interconnect layer 26, the insulating layer 20 may be called a receiving layer. The second interconnect layer 26 is formed to come in contact with the first interconnect layer 14 through the contact hole 24. In the case of forming the second interconnect layer 26 by using a solvent containing conductive particles, the solvent may be ejected into the contact hole 24.

As shown in FIG. 2C, the conductive particles in the second interconnect layer 26 may be bonded together by applying heat. The insulating layer 20 and the second interconnect layer 26 may have the features described for the receiving layer 10 and the first interconnect layer 14, and achieve the same effects.

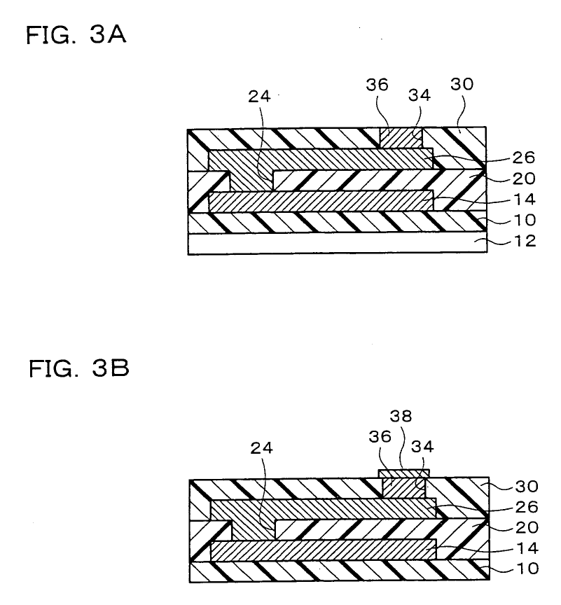

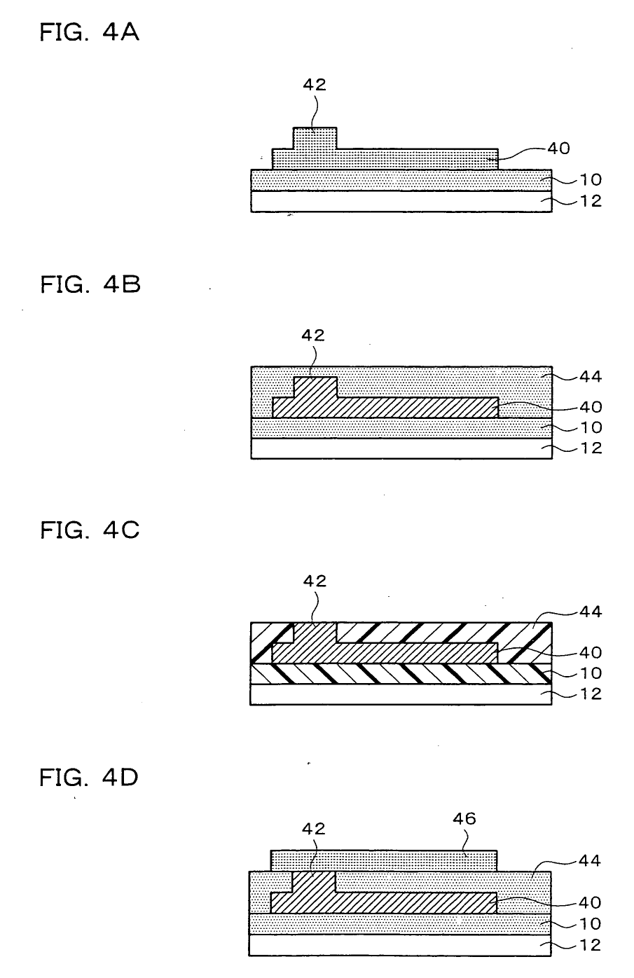

As shown in FIG. 3A, a third insulating layer 30 may be formed on the insulating layer 20 (second insulating layer) so as to cover the second interconnect layer 26. The description of the insulating layer 20 may be applied to the material for the third insulating layer 30. A contact hole 34 may be formed in the third insulating layer 30. A contact post 36 may be formed on the second interconnect layer 26 through the contact hole 34.

As shown in FIG. 3B, a terminal section 38 may be formed on the contact post 36. The terminal section 38 may be formed to be larger than the upper surface of the contact post 36. In this case, the peripheral section of the terminal section 38 may be placed on the third insulating layer 30. The terminal section 38 may be formed by electroless plating of Ni, Cu, or the like.

The base material 12 may be removed from the receiving layer 10. For example, a copper plate may be used as the base material 12, and the base material 12 may be dissolved by immersing the base material 12 in an etchant such as ferric chloride. This step is performed after causing the conductive particles (first and second interconnect layers 14 and 26) to be bonded together. This enables a thin stacked wiring board to be obtained.

According to the present embodiment, the hardened receiving layer 10 has high adhesion to the interconnect layer 14 including the bonded conductive particles. Therefore, a highly reliable wiring board can be easily manufactured.

### Second Embodiment

FIGS. 4A to 4D are illustrative of a method of manufacturing a wiring board according to a second embodiment of the present invention. In the present embodiment, an interconnect layer 40 is formed on the receiving layer 10, as shown in FIG. 4A. The base material 12 may be used. The interconnect layer 40 is formed to include a contact post 42. The description of the first embodiment may be applied to the material and the formation method for the receiving layer 10 and the interconnect layer 40. Specifically, the interconnect layer 40 is formed on the receiving layer 10 in a softened state, and the conductive particles are bonded together by heating the interconnect layer 40.

As shown in FIG. 4B, an insulating layer 44 is formed on the receiving layer 10 so as to cover the interconnect layer 40. The insulating layer 44 may cover the contact post 42. The description of the insulating layer 20 in the first embodiment may be applied to the material and the formation method for the insulating layer 44. The insulating layer 44 may be formed after causing the conductive particles in the interconnect layer 40 to be bonded together. The insulating layer 44 is removed in the area located on the contact post 42. This removal step may be performed in a state in which the thermoplastic resin which makes up the insulating layer 44 is softened, or may be performed after the thermoplastic resin is hardened. This removal step may be performed by dissolving the surface of the insulating layer 44. The upper surface of the contact post 42 is thus exposed, as shown in FIG. 4C.

As shown in FIG. 4D, a second interconnect layer 46 is formed on the insulating layer 44. The description of the second interconnect layer 26 in the first embodiment may be applied to the material and the formation method for the second interconnect layer 46. Since the insulating layer 44 has the same function as the receiving layer 10 for the second interconnect layer 46, the insulating layer 44 may be called a receiving layer. The second interconnect layer 26 is formed to pass over the contact post 42. The conductive particles in the second interconnect layer 46 are then bonded together, whereby a stacked wiring board can be manufactured. The description of the first embodiment may be applied to the present embodiment. In the present embodiment, the effects described in the first embodiment can also be achieved.

### Third Embodiment

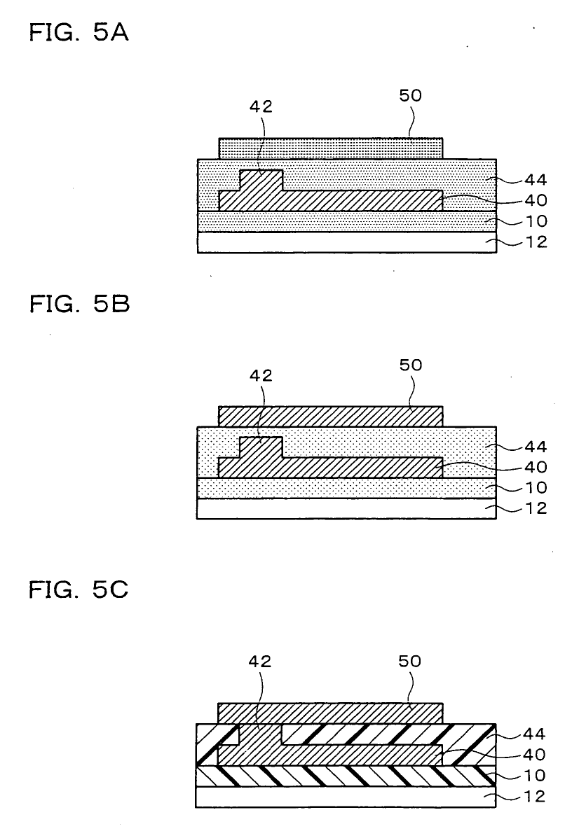

FIGS. 5A to 5C are illustrative of a method of manufacturing a wiring board according to a third embodiment of the present invention. In the present embodiment, the interconnect layer 40 is formed on the receiving layer 10, and the insulating layer 44 is formed on the interconnect layer 40 in the same manner as described in the second embodiment. The insulating layer 44 is formed to cover the contact post 42. The other details are the same as the details described with reference FIGS. 4A and 4B.

As shown in FIG. 5A, a second interconnect layer 50 is formed on the insulating layer 44 in a state in which the thermoplastic resin which makes up the insulating layer 44 is softened. The description of the second interconnect layer 26 in the first embodiment may be applied to the material and the formation method for the second interconnect layer 50. Since the insulating layer 44 has the same function as the receiving layer 10 for the second interconnect layer 50, the insulating layer 44 may be called a receiving layer. A part of the insulating layer 44 is present between the second interconnect layer 50 and the contact post 42 in this state.

As shown in FIG. 5B, the conductive particles in the second interconnect layer 50 are bonded together by applying heat. The insulating layer 44 may be softened (further softened) by the applied heat. A pressure may be applied to the second interconnect layer 50 and the interconnect layer 40 in the directions in which the second interconnect layer 50 and the interconnect layer 40 are each pressed against the other after causing the conductive particles to be bonded together so as to form a conductive film or a conductive layer.

This causes the contact post 42 to be electrically connected with the second interconnect layer 50, as shown in FIG. 5C. A stacked wiring board can be manufactured in this manner. The description of the first embodiment may be applied to the present embodiment. In the present embodiment, the effects described in the first embodiment can also be achieved.

### Fourth Embodiment

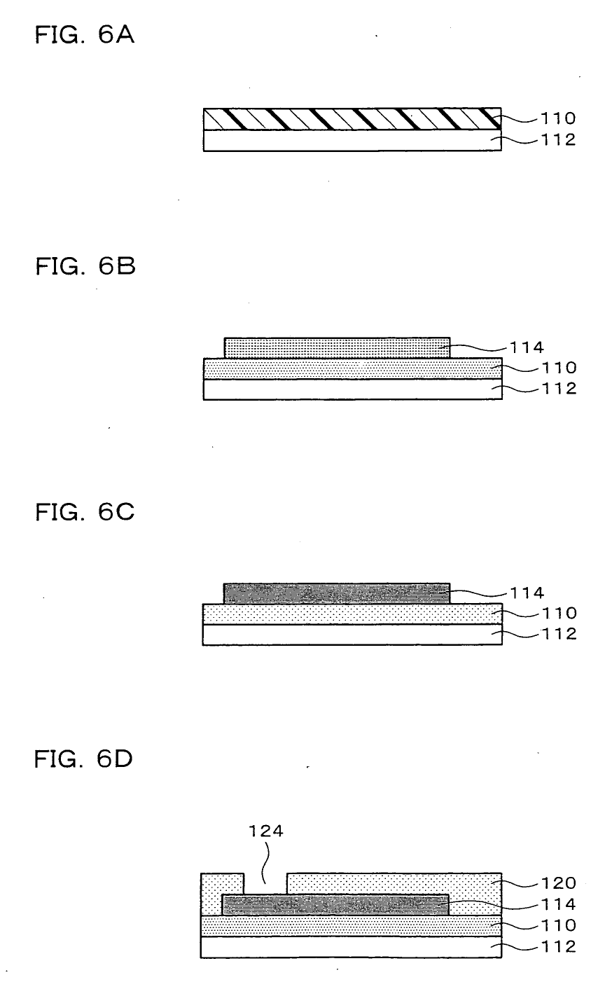

FIGS. 6A to 9B are illustrative of a method of manufacturing a wiring board (stacked wiring board) according to a fourth embodiment of the present invention. In the present embodiment, a receiving layer 110 formed by using a thermoplastic resin (organic material such as a polyamide or a thermoplastic polyimide, for example) is used, as shown in FIG. 6A. The first receiving layer 110 may be formed on a base material 112 (substrate, for example). The base material 112 may be formed of a metal such as copper, a thermosetting resin (polyimide or epoxy resin, for example), or glass. The first receiving layer 110 may be formed to have a flat surface. The first receiving layer 110 has insulating properties and may be called a first insulating layer.

As shown in FIG. 6B, the first receiving layer 110 is softened by applying heat. The first receiving layer 110 may be formed by using a thermoplastic resin in a softened state. The receiving layer 110 may have viscosity in a softened state. A first interconnect layer 114 is formed on the first receiving layer 110 in a softened state. The first interconnect layer 114 is formed by using a solvent containing conductive particles (metallic ink, for example). The conductive particles may be formed of a material which is rarely oxidized and has a low electrical resistance, such as gold or silver. As a solvent containing fine gold particles, “Perfect Gold” (manufactured by Vacuum Metallurgical Co., Ltd.) may be used. As a solvent containing fine silver particles, “Perfect Silver” (manufactured by Vacuum Metallurgical Co., Ltd.) may be used. There are no specific limitations to the size of the particles. The particles used herein are particles which can be ejected together with a solvent. The first interconnect layer 114 may be formed by ejecting a solvent containing conductive particles using an ink-jet method or a Bubble Jet (registered trademark) method, or may be formed by mask printing or screen printing. The conductive particles may be covered with a coating material in order to prevent a reaction between the particles. The solvent may be dried to only a small extent and have resolubility. The conductive particles may be uniformly dispersed in a solvent.

According to the present embodiment, since the solvent containing conductive particles is provided on the thermoplastic resin in a softened state, occurrence of blurring or bulging can be prevented when forming the interconnect layer 114. The conductive particles (or conductive particles and coating material) may be allowed to remain by drying the first interconnect layer 114 to volatilize the solvent. The first interconnect layer 114 may be dried at a temperature from room temperature or more to 1 00C or less.

As shown in FIG. 6C, heat may be applied to the first interconnect layer 114. The coating material which covers the conductive particles may be decomposed by the applied heat. A gas may be generated when decomposing the coating material. The thermoplastic resin may be further softened.

As shown in FIG. 6D, a second receiving layer 120 is formed on the first interconnect layer 114 and the first receiving layer 110. The second receiving layer 120 is formed by using a thermoplastic resin. The description of the first receiving layer 110 may be applied to the material and the formation method for the second receiving layer 120. The second receiving layer 120 has insulating properties and may be called a second insulating layer. The solvent is volatilized from at least the first interconnect layer 114 before forming the second receiving layer 120. A contact hole 124 is formed in the second receiving layer 120.

The second receiving layer 120 is formed in a softened state. For example, the second receiving layer 120 may be formed in a hardened state and then softened, or the second receiving layer 120 may be formed by using a softened thermoplastic resin.

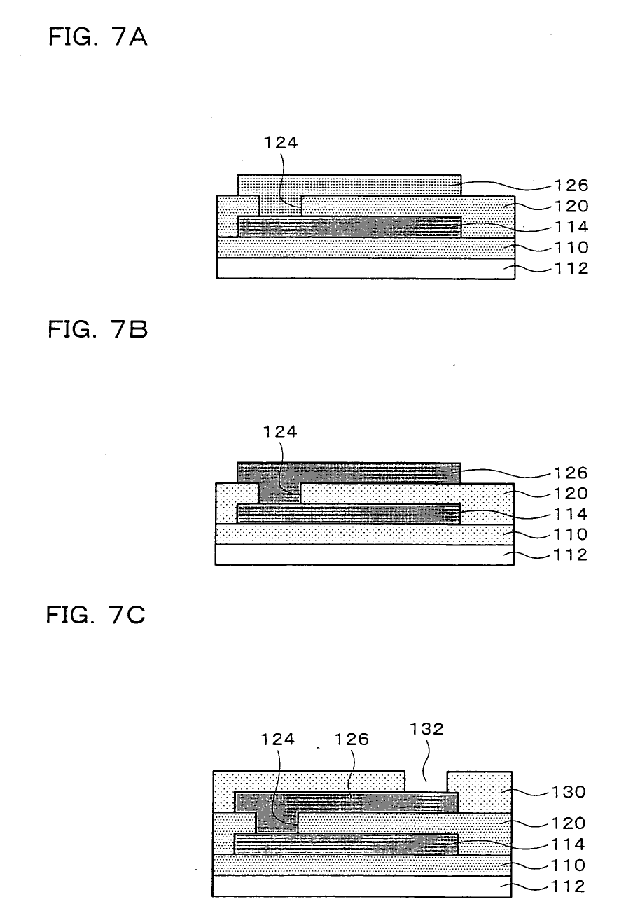

As shown in FIG. 7A, a second interconnect layer 126 is formed on the second receiving layer 120. The second interconnect layer 126 is formed by using a solvent containing conductive particles. The description of the first interconnect layer 114 may be applied to the material and the formation method for the second interconnect layer 126. The second interconnect layer 126 is formed to come in contact with the first interconnect layer 114 through the contact hole 124. In the case of forming the second interconnect layer 126 by using a solvent containing conductive particles, the solvent may be ejected into the contact hole 124.

As shown in FIG. 7B, heat may be applied to the second interconnect layer 126. The coating material which covers the conductive particles may be decomposed by the applied heat. A gas may be generated when decomposing the coating material. The thermoplastic resins which make up the first and second receiving layers 110 and 120 may be further softened.

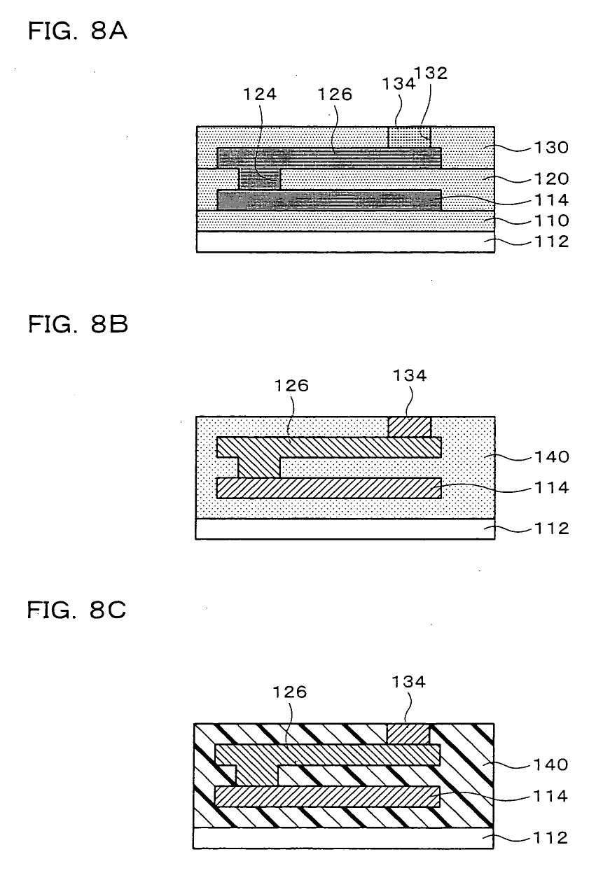

As shown in FIG. 7C, a third receiving layer 130 may be formed on the second interconnect layer 126 and the second receiving layer 120. The third receiving layer 130 is formed by using a thermoplastic resin. The description of the first receiving layer 110 may be applied to the material and the formation method for the third receiving layer 130. The third receiving layer 130 has insulating properties and may be called a third insulating layer. A contact hole 132 may be formed in the third insulating layer 130. As shown in FIG. 8A, a contact post 134 may be formed in the contact hole 132. The material and the formation method for the first interconnect layer 114 may be applied to the material and the formation method for the contact post 134.

Heat is applied to the first and second receiving layers 110 and 120 (and the third receiving layer 130). The first and second receiving layers 110 and 120 (and the third receiving layer 130) are softened by the applied heat to adhere. As shown in FIG. 8B, the first and second receiving layers 110 and 120 (and the third receiving layer 130) may be integrally softened to form an integral insulating layer 140. This prevents occurrence of interlayer separation between the first and second receiving layers 110 and 120 (and the third receiving layer 130).

The first and second receiving layers 110 and 120 may be heated at a temperature at which the conductive particles are bonded together (sintered, for example) in the connecting portion of the first and second interconnect layers 114 and 126 (about 300-600° C., for example). The heat may be applied for about one hour. The conductive particles form a conductive film or a conductive layer.

As shown in FIG. 8C, after the thermoplastic resins which make up the first and second receiving layers 110 and 120 (and the third receiving layer 130) are hardened and the conductive particles are bonded together, the first and second interconnect layers 114 and 126 have high adhesion to the insulating layer 140 (adhesion between the first interconnect layer 114 and the first and second receiving layers 110 and 120, or adhesion between the second interconnect layer 126 and the second and third receiving layers 120 and 130, in more detail), whereby a highly reliable wiring board (stacked wiring board) is obtained. The conductive particles in the contact post 134 may be bonded together (sintered, for example) in the same manner as described above.

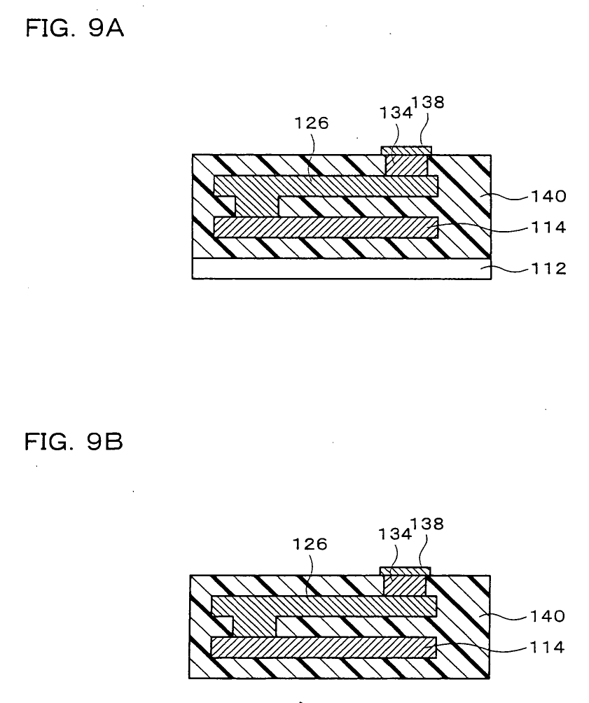

As shown in FIG. 9A, a terminal section 138 may be formed on the contact post 134. The terminal section 138 may be formed to be larger than the upper surface of the contact post 134. In this case, the peripheral section of the terminal section 138 may be placed on the insulating layer 140 (or the third receiving layer 130). The terminal section 138 may be formed by electroless plating of Ni, Cu, or the like.

As shown in FIG. 9B, the base material 112 may be removed from the first receiving layer 110. For example, a copper plate may be used as the base material 112, and the base material 112 may be dissolved by immersing the base material 112 in an etchant such as ferric chloride. This step is performed after causing the thermoplastic resins (first, second, and third receiving layers 110, 120, and 130) to be hardened and the conductive particles (connecting portion of the first and second interconnect layers 114 and 126) to be bonded together.

According to the present embodiment, the first and second interconnect layers 114 and 126 have high adhesion to the insulating layer 140. Therefore, a highly reliable wiring board (stacked wiring board) can be easily manufactured.

### Fifth Embodiment

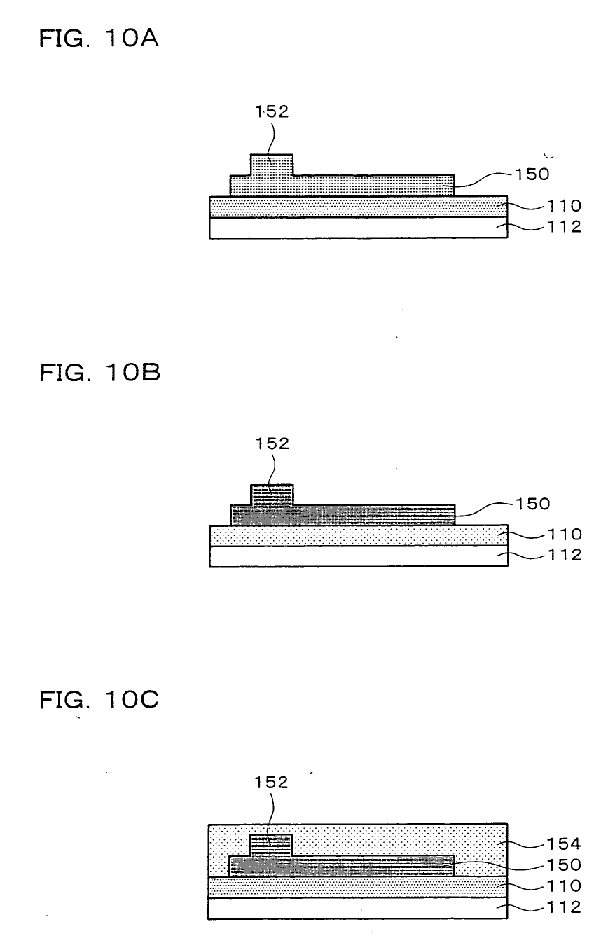

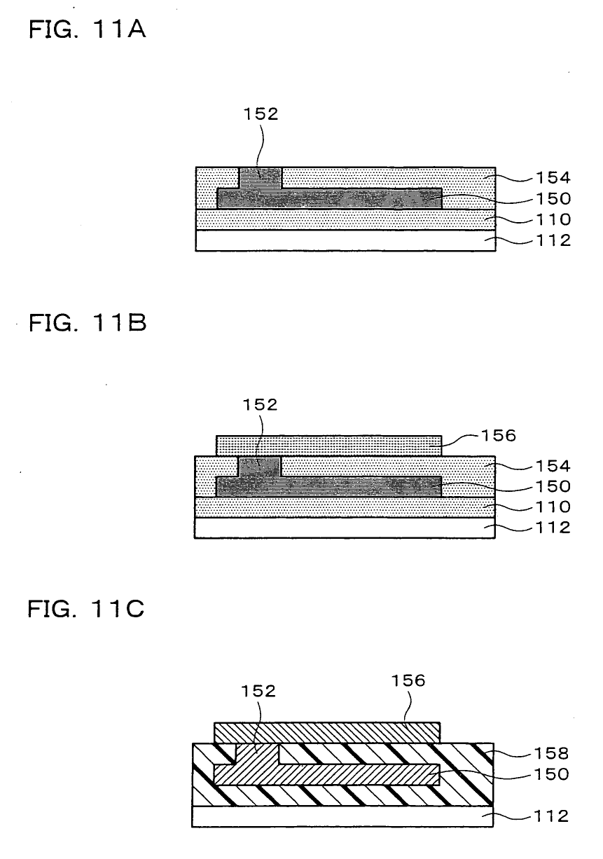

FIGS. 10A to 11C are illustrative of a method of manufacturing a wiring board (stacked wiring board) according to a fifth embodiment of the present invention. In the present embodiment, a first interconnect layer 150 is formed on the first receiving layer 110, as shown in FIG. 10A. The base material 112 may be used. The first interconnect layer 150 is formed to include a contact post 152. The description of the first interconnect layer 114 may be applied to the material and the formation method for the first interconnect layer 150.

As shown in FIG. 10B, the coating material which covers the conductive particles in the first interconnect layer 150 may be decomposed by applying heat. A gas may be generated when decomposing the coating material. The thermoplastic resin which makes up the first receiving layer 110 may be further softened.

As shown in FIG. 10C, a second receiving layer 154 is formed on the first interconnect layer 150 and the first receiving layer 110. The second receiving layer 154 may cover the contact post 152. The description of the second receiving layer 120 in the fourth embodiment may be applied to the material and the formation method for the second receiving layer 154.

As shown in FIG. 11A, at least the upper surface of the contact post 152 is exposed from the second receiving layer 154. The surface of the second receiving layer 154 may be removed so that the second receiving layer 154 becomes thinner. The surface of the second receiving layer 154 may be dissolved.

As shown in FIG. 11B, a second interconnect layer 156 is formed on the second receiving layer 154. The description of the second interconnect layer 126 in the fourth embodiment may be applied to the material and the formation method for the second interconnect layer 156. The second interconnect layer 156 is formed to pass over the contact post 152.

As shown in FIG. 11C, the thermoplastic resins of the first and second receiving layers 110 and 154 are softened by applying heat. An integral insulating layer 158 may be formed by this step. The conductive particles are bonded together in the connecting portion of the first and second interconnect layers 150 and 156 by applying heat. A wiring board (stacked wiring board) is manufactured in this manner. The description of the fourth embodiment may be applied to the present embodiment. In the present embodiment, the effects described in the fourth embodiment can also be achieved.

### Sixth Embodiment

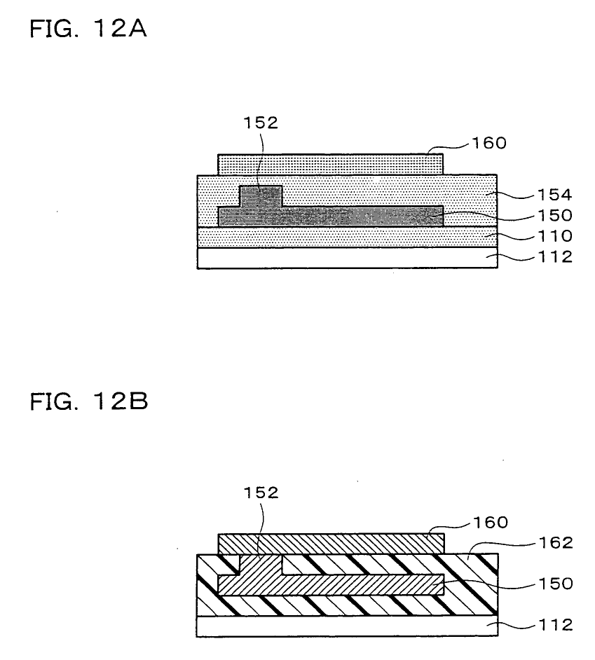

FIGS. 12A and 12B are illustrative of a method of manufacturing a wiring board (stacked wiring board) according to a sixth embodiment of the present invention. In the present embodiment, the first interconnect layer 150 is formed on the first receiving layer 110, and the second receiving layer 154 is formed on the first interconnect layer 150 in the same manner as described in the fifth embodiment. The second receiving layer 154 is formed to cover the contact post 152. The other details are the same as the details described with reference FIG. 10C.

As shown in FIG. 12A, a second interconnect layer 160 is formed on the second receiving layer 154 in a state in which the thermoplastic resin which makes up the second receiving layer 154 is softened. The description of the second interconnect layer 126 in the fourth embodiment may be applied to the material and the formation method for the second interconnect layer 160. A part of the second receiving layer 154 is present between the second interconnect layer 160 and the contact post 152 in this state.

The conductive particles are bonded together in the connecting portion of the first and second interconnect layers 150 and 160 by applying heat. The first and second receiving layers 110 and 154 may be softened (further softened) by the applied heat. The first and second receiving layers 110 and 154 may form an integral insulating layer 162. A pressure may be applied to the second interconnect layer 150 and the interconnect layer 160 in the directions in which the second interconnect layer 150 and the interconnect layer 160 are each pressed against the other after causing the conductive particles to be bonded together so as to form a conductive film or a conductive layer.

This causes the contact post 152 to be electrically connected with the second interconnect layer 160, as shown in FIG. 12B. A wiring board (stacked wiring board) is manufactured in this manner. The description of the fourth embodiment may be applied to the present embodiment. In the present embodiment, the effects described in the fourth embodiment can also be achieved.

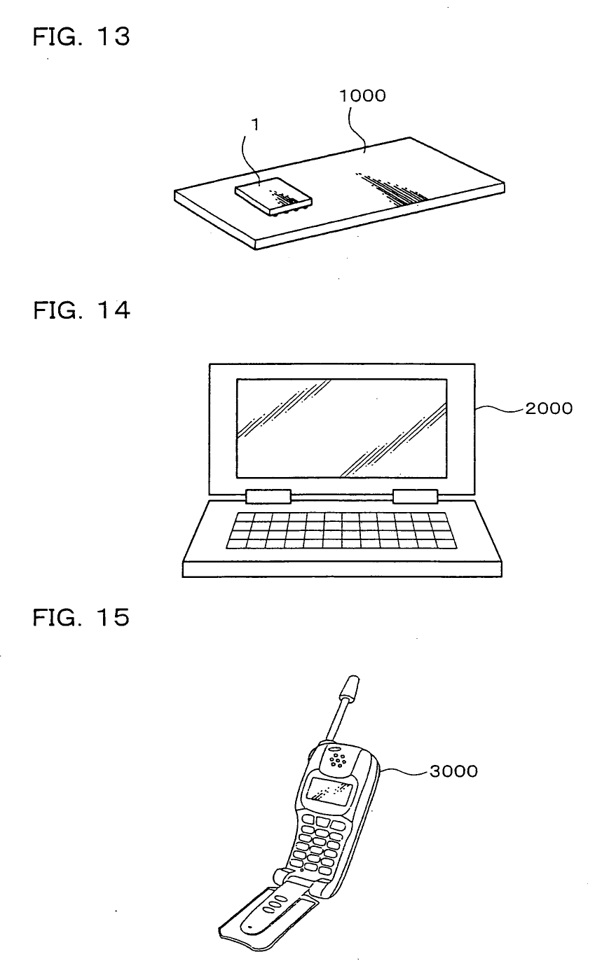

FIG. 13 shows a semiconductor device which includes a wiring board 1000 (or stacked wiring board) described in one of the above embodiments, and a semiconductor chip 1 electrically connected with the wiring board 1000. FIGS. 14 and 15 respectively show a notebook-type personal computer 2000 and a portable telephone 3000 as examples of electronic instruments including the semiconductor device.

The present invention is not limited to the above-described embodiments. Various modifications and variations are possible. For example, the present invention includes configurations essentially the same as the configurations described in the embodiments (for example, configurations having the same function, method, and results, or configurations having the same object and results). The present invention includes configurations in which any unessential part of the configuration described in the embodiments is replaced. The present invention includes configurations having the same effects or achieving the same object as the configurations described in the embodiments. The present invention includes configurations in which conventional technology is added to the configurations described in the embodiments.

What is claimed is:

1. A method of manufacturing a wiring board, comprising:
forming a first interconnect layer on a first receiving layer formed of a thermoplastic resin which has been in a softened state by using a solvent containing conductive particles;
forming a second receiving layer in a softened state on the first receiving layer and the first interconnect layer by using a thermoplastic resin;
forming a second interconnect layer on the second receiving layer which has been in the softened state by using a solvent containing conductive particles; and
causing the thermoplastic resins of the first and second receiving layers to be softened and the conductive particles to be bonded together in a connecting portion of the first and second interconnect layers by applying heat.

2. The method of manufacturing a wiring board as defined in claim 1,
wherein the conductive particles included in the first interconnect layer are dispersed in the solvent in a state in which each of the conductive particles is covered with a coating material for preventing a reaction between the conductive particles, and
wherein the method further includes decomposing the coating material by heating the first interconnect layer before forming the second receiving layer.

3. The method of manufacturing a wiring board as defined in claim 1,
wherein the first and second interconnect layers are formed by ejecting the solvent containing the conductive particles.

4. The method of manufacturing a wiring board as defined in claim 1,
wherein the first receiving layer is formed on a base material.

5. The method of manufacturing a wiring board as defined in claim 1, further comprising:
removing the base material from the first receiving layer after causing the conductive particles to be bonded together in the connecting portion of the first and second interconnect layers.
